(19) United States
(12) Patent Application Publication
(10) Pub. No.: US 2017/0170245 A1
(43) Pub. Date: Jun. 15, 2017

(54) ORGANIC LIGHT EMITTING DIODE DISPLAY AND METHOD FOR MANUFACTURING THE SAME

(71) Applicant: EVERDISPLAY OPTRONICS (SHANGHAI) LIMITED, Shanghai City (CN)

(72) Inventor: Maochung LIN, SHANGHAI CITY (CN)

(73) Assignee: EVERDISPLAY OPTRONICS (SHANGHAI) LIMITED, SHANGHAI CITY (CN)

(21) Appl. No.: 15/235,534

(22) Filed: Aug. 12, 2016

(30) Foreign Application Priority Data
Dec. 14, 2015 (CN) 201510929000.4

(51) Int. Cl. H01L 27/32; H01L 51/52

(52) U.S. Cl. CPC H01L 27/3246; H01L 27/322; H01L 27/3216; H01L 51/5253; H01L 2227/323

(57) ABSTRACT

The present disclosure relates to an organic light emitting diode display. The display includes: a substrate; a thin film transistor array disposed on the substrate; a light emitting module including: a pixel-defining layer disposed on the thin film transistor array and provided with a plurality of openings for defining positions of pixels; and a plurality of light emitting units disposed on the thin film transistor array and in the openings of the pixel-defining layer; color filter units on the light emitting module which are disposed in the openings of the pixel-defining layer so that the color filter units corresponds to the light emitting units in the openings of the pixel-defining layer; and a package layer disposed on and covering the color filter units. The organic light emitting diode display in the present disclosure may be applied into large-sized displays and meet lighting and thinning requirements.

### CROSS-REFERENCE TO RELATED APPLICATIONS

This application claims priority to Chinese Patent Application No. 201510929000.4, filed Dec. 14, 2015, the entire contents of which are incorporated herein by reference.

### TECHNICAL FIELD

The present disclosure generally relates to display technologies, and more particularly to, an organic light emitting diode display and a method for manufacturing the same.

### BACKGROUND

Conventional organic light emitting diode (OLED) displays usually employ an RGB pixel arrangement. As shown in FIG. 1, a thin film transistor array 12 is disposed on a first substrate 11, light emitting units 13 are disposed on the thin film transistor array 12, a second substrate 15 is attached to the first substrate 11 via an adhesive layer 14 to enclose the thin film transistor array 12 and the light emitting units 13 into a closed space. Light emitting materials are excited by electricity to emit light of colors such as red, green and blue so that a full color OLED display is achieved.

Recently, displays are designed as having increasingly large size, and accordingly higher accuracy requirements on substrate glass and evaporation masks are proposed. This causes neck bottle in mass production of OLED displays. In order to address such issue, a part of OLED displays employ a structure of white OLED plus color filter (CF) units. As shown in FIG. 2, color filter units 26 are disposed on a lower surface of a second substrate 25, white light emitting units 23 are disposed on a thin film transistor array 22. The white light emitting units 23 are excited to emit white light which is then filtered by the color filter units 26 to display light of red, green and blue, so that a full color OLED display is realized.

However, the OLED display with the structure of white OLED plus color filter units has the following defects. For example, a distance from the light emitting units 23 to the color filter units 26 is hard to control, additional processes are needed to make the thickness of the display meet the lighting and thinning requirements, and such OLED structure cannot be applied into a flexible display.

### SUMMARY

Aiming at the shortcomings in conventional technologies, embodiments of the present disclosure provide an organic light emitting diode display having a novel structure which can not only be applied into large-sized displays, but also meet lighting and thinning requirements.

Embodiments of the present disclosure provide an organic light emitting diode display, including:

a substrate;

a thin film transistor array disposed on the substrate;

a light emitting module comprising:

a pixel-defining layer disposed on the thin film transistor array and provided with a plurality of openings for defining positions of pixels; and

a plurality of light emitting units disposed on the thin film transistor array and in the openings of the pixel-defining layer;

color filter units disposed on the light emitting module and corresponding to positions of the plurality of light emitting units in the openings of the pixel-defining layer; and

a package layer disposed on the substrate to cover the color filter units.

Optionally, the light emitting module further includes a blocking layer disposed on the plurality of light emitting units and covering the plurality of light emitting units and the thin film transistor array.

Optionally, the blocking layer is a thin film package layer.

Optionally, the package layer is a thin film package layer.

Optionally, the thin film package layer is made of a material selected from oxide, nitride, oxynitride or fluoride.

Optionally, the organic light emitting diode display further includes:

an adhesive layer disposed on the color filter units;

wherein the package layer is attached to the color filter units via the adhesive layer.

Optionally, the organic light emitting diode display further includes:

an adhesive layer disposed at an edge of the substrate;

wherein the package layer and the substrate are adhered with each other via the adhesive layer.

Optionally, the package layer is a flexible layer or a rigid layer.

Optionally, the organic light emitting diode display further includes:

a black matrix disposed between two adjacent color filter units.

Optionally, the light emitting units are white light emitting units.

Or, the light emitting units include individual red, green and blue light emitting units.

Optionally, the substrate is a flexible substrate or a rigid substrate.

Embodiments of the present disclosure further provide a method for manufacturing an organic light emitting diode display, including steps of:

S1: providing a thin film transistor array on a substrate;

S2: providing a light emitting module on the thin film transistor array having a pixel-defining layer and a plurality of light emitting units thereon;

S3: providing color filter units on the light emitting module; and

S4: providing a package layer on the color filter units, wherein the package layer covers the color filter units.

Optionally, the light emitting module provided in the step S2 further includes a blocking layer which is disposed on the plurality of light emitting units and covers the light emitting units and the thin film transistor array.

Optionally, the step S4 further includes: providing an adhesive layer on the color filter units such that the package layer is attached to the color filter units via the adhesive layer.

Optionally, the step S4 further includes: providing an adhesive layer at an edge of the substrate so that the package layer and the substrate are adhered with each other via the adhesive layer.

Optionally, the step S3 further includes: providing a black matrix on the light emitting module, wherein the black matrix is disposed between two adjacent color filter units.

Optionally, the color filter units and the black matrix are manufactured by ink jet printing.

The organic light emitting diode display and the method for manufacture thereof in the present disclosure have the following advantageous effects over conventional technologies:

(1) The organic light emitting diode display and the method for manufacture thereof in the present disclosure can be applied into large-sized displays and meet lighting and thinning requirements.

(2) The organic light emitting diode display and the method for manufacture thereof in the present disclosure can be applied into not only white OLED displays but also red, green and blue OLED displays.

(3) When the package layer of the organic light emitting diode display in the present display is a thin film package layer or a flexible substrate package, the organic light emitting diode display in the present disclosure can be applied into flexible displays.

### BRIEF DESCRIPTION OF THE DRAWINGS

FIG. 1 is a schematic diagram showing a conventional organic light emitting diode display.

FIG. 2 is a schematic diagram showing a white organic light emitting diode display in conventional technologies.

FIG. 3 is a schematic diagram showing an organic light emitting diode display according to an embodiment of the present disclosure.

FIGS. 4A and 4B are schematic diagrams showing an organic light emitting diode display according to another embodiment of the present disclosure.

FIG. 5 is a schematic diagram showing an organic light emitting diode display according to another embodiment of the present disclosure.

FIG. 6 is a flowchart showing a method for manufacturing an organic light emitting diode display according to an embodiment of the present disclosure.

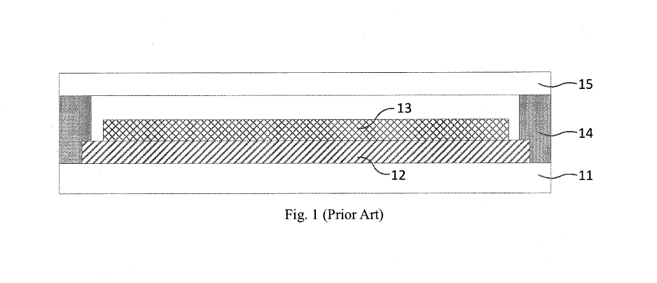

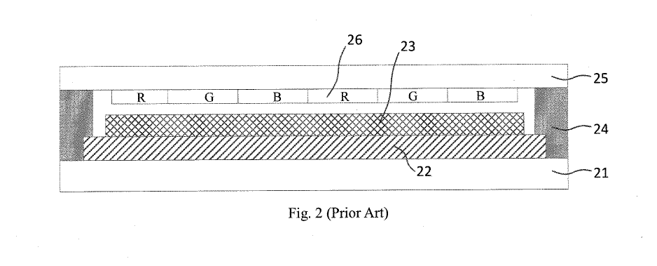

### LISTING OF REFERENCE SIGNS

| | |
|---|---|
| 11, 21, 31: first substrate | 12, 22, 32: thin film transistor array |
| 13, 23, 33: light emitting units | 14, 24, 34: adhesive layer |
| 15, 25: second substrate | 35: blocking layer |
| 26, 36: color filter units | 37: package layer |
| 38: pixel-defining layer | 39: black matrix |

### DETAILED DESCRIPTION

Now, exemplary implementations will be described more comprehensively with reference to the accompanying drawings. However, the exemplary implementations may be carried out in various manners, and shall not be interpreted as being limited to the implementations set forth herein; instead, providing these implementations will make the present disclosure more comprehensive and complete and will fully convey the conception of the exemplary implementations to the ordinary skills in this art. Throughout the drawings, the like reference numbers refer to the same or the like structures, and repeated descriptions will be omitted.

The terms for expressing positions and directions throughout the present disclosure are based on drawings for illustrative purposes, and can be changed as required, and such changes shall be encompassed in the scope of the present disclosure. The words “upper/lower/middle”, or “on/below/between” mentioned herein shall be interpreted as one layer, part or film and the like is directly on or below another layer, part or film and the like, or one layer, part, or film is directly inserted between two layers, films or parts, or one layer, part or film is indirectly on or below another layer, part or film, or there is intervention layers, films or parts therebetween.

### First Embodiment

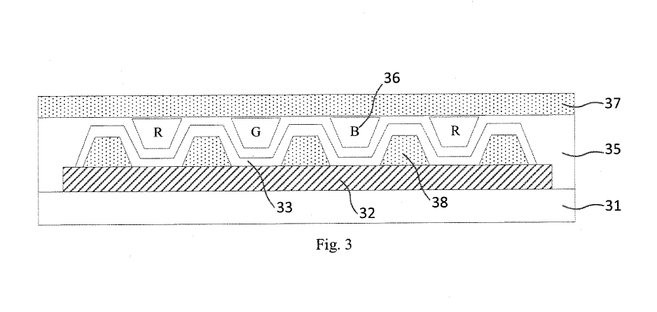

FIG. 3 is a schematic diagram showing an organic light emitting diode display according to an embodiment of the present disclosure. Referring to FIG. 3, the organic light emitting diode display includes a first substrate 31; a thin film transistor array 32 disposed on the first substrate 31; a light emitting module including a pixel-defining layer 38 and a plurality of light emitting units 33, wherein the pixel-defining layer 38 is disposed on the thin film transistor array 32 and provided with a plurality of openings for defining positions of pixels, and the plurality of light emitting units 33 are disposed on the thin film transistor array 32 and in the openings of the pixel-defining layer 38; color filter units 36 disposed on the light emitting module and corresponding to positions of the plurality of light emitting units 33 in the openings of the pixel-defining layer 38; and a package layer 37 disposed on and covering the color filter units 36.

The first substrate 31 may be a flexible substrate or a rigid substrate. The flexible substrate includes a metal substrate, an organic polymer substrate, or metal oxide substrate and the like. As an example, the first substrate 31 is an organic polymer substrate, for example, polyethylene terephthalate, polyether sulfone, polyethylene naphthalate, cycloolefin copolymer or polyimide. The rigid substrate includes a glass substrate, a quartz substrate and the like.

The thin film transistor array 32 may include an active layer, a gate, a gate insulation layer, a source, a drain, a passivation layer, a planarization layer and the like, which may be formed as existing structures by known preparation processes such as deposition, etching, and the like.

The light emitting units 33 may be white light emitting units, or the light emitting units 33 may include individual red, green and blue light emitting units. The white light emitting units are those light emitting units which only emit light of white color, and can be formed by combining RGB light emitting layers or host and dopant materials and the like. The individual red, green and blue light emitting units are those light emitting units which emit light of three-primary colors, i.e., red, green and blue (subpixels). The three-primary colors are fixed to represent the color of one pixel. The red, green and blue light emitting units can be formed by selecting different host and dopant light emitting materials.

Each of the light emitting units 33 may include an anode, a cathode, and an organic function layer between the anode and the cathode. The organic function layer at least includes a light emitting layer. The organic function layer may further include one or more of a hole injection layer, a hole transportation layer, an electron blocking layer, a hole blocking layer, an electron transportation layer, an electron injection layer. The anode, the cathode and the organic function layer may be formed using well known materials and preparation methods.

The pixel-defining layer 38 is disposed between adjacent light emitting units 33. The pixel-defining layer 38 is disposed on the thin film transistor array 32 and provided with a plurality of openings for defining positions of pixels as well as red, green and blue light emitting regions of the organic light emitting diode display.

Optionally, the light emitting module may further include a blocking layer 35 disposed on the plurality of light emitting units 33. The blocking layer 35 covers the plurality of light emitting units 33 and the thin film transistor array 32. When the light emitting module includes the blocking layer 35, the color filter units 36 may be directly disposed on the blocking layer 35. Alternatively, the blocking layer 35 may be omitted from the embodiments of the present disclosure, and then the color filter units 36 may be directly disposed on the light emitting units 33.

The blocking layer 35 may be a first thin film package layer which may be formed by materials including but not limited to oxide, nitride, oxynitride, fluoride. As an exemplary embodiment, the blocking layer is formed by oxide, or nitride. The oxide may include but not limited to aluminium oxide, zirconia, zinc oxide, titanium oxide, magnesium oxide, silicon oxide, or silicon oxycarbide. The nitride may include but not limited to silicon nitride, aluminium nitride, or titanium nitride. The oxynitride may include but not limited to silicon oxynitride, aluminum oxynitride, titanium or oxynitride. The fluoride may include but not limited to magnesium fluoride or sodium fluoride.

The blocking layer 35 formed by inorganic materials have good water and oxygen resistance property and can effectively block water and oxygen in ambient environment from invading into the function layers of the light emitting units 33 and the thin film transistor array 32, and thus can extend lifetime of the display.

The color filter units 36 are disposed on the light emitting module and disposed in the openings of the pixel-defining layer 38 so that the color filter units 36 corresponds to the light emitting units 33 in the openings of the pixel-defining layer 38. By such arrangement, the color filter units do not occupy additional space, which is beneficial for reducing the thickness of the display and controlling distance between the light emitting units 33 and the color filter units 36, and thus the lighting and thinning requirements of large-sized display can be meet.

The color filter units 36 include photoresist layers of three colors (red, green and blue) which are arranged on the pixels formed by the light emitting units 33 in order. In an embodiment, the color filter units 36 in the present disclosure are directly formed on the blocking layer 36 which is formed on the light emitting units 33 (that is, the color filter units 36 are formed at positions on the blocking layer which are directly corresponding to the light emitting units 33). Thus, the technical problem that the distance between the light emitting units 33 and the color filter units 36 is hard to control can be overcome.

When the light emitting units 33 are white light emitting units, the color filter units 36 are used to achieve a full color effect. The organic light emitting diode display of such structure has high aperture ratio, can be applied into large-sized displays and has high production yield.

When the light emitting units 33 are individual light emitting units of red, green and blue, the organic light emitting diode display of such structure can adjust the chromaticity value of the red, green and blue colors by using the color filter units 36.

The package layer 37, serving as a buffer layer or a protection layer, prevents the color filter units 36 from scratch, and also plays a role of water or oxygen resistance and extension of lifetime of the display.

Embodiments of the present disclosure also provide a method for manufacturing an organic light emitting diode display which may include the following steps.

In step S1, a thin film transistor array 32 is provided on a first substrate 31.

In step S2, a light emitting module is provided on the thin film transistor array 32. The light emitting module includes a plurality of light emitting units 33 and a pixel-defining layer 38.

In steps S1 and S2, the thin film transistor array 32, the light emitting units 33 and the pixel-defining layer 38 can be provided using known common methods and detailed descriptions are not elaborated herein.

In an embodiment, the light emitting module in the above preparation step may further include a blocking layer 35 which is disposed on the plurality of light emitting units 33 and covers the light emitting units 33 and the thin film transistor array 32.

The blocking layer 35 is a first thin film package layer, and may be provided by existing methods such as PECVD (Plasma Enhanced Chemical Vapor Deposition), ALD (Atomic Layer Deposition), sputter and the like. The resulted blocking layer 35 may have a thickness of 50 nm to 2000 nm.

In step S3, color filter units 36 are provided on the light emitting module.

The color filter units 36 may be formed by ink jet printing. Specifically, in an embodiment, by means of an ink jet device, ink of different colors are injected onto the blocking layer 35 on different light emitting units 33 using a patterning process to form the patterns of the color filter units 36. The patterning process includes forming a color filter film on the blocking layer 35, and performing exposure, developing and etching on the color filter film to form the patterns of the color filter units 36. The color filter units 36 include color filter units of red, green and blue.

In step S4, a package layer 37 is provided on the color filter units 36, wherein the package layer 37 covers the color filter units 36.

The package layer 37 in the present embodiment is a second thin film package layer. The second thin film package layer may be formed using the same materials and preparation methods as that of the first thin film package layer, and the second thin film package layer may be of the same thickness as that of the first thin film package layer.

By using the above main steps, the preparation of the organic light emitting diode display is completed.

In the organic light emitting diode display in the present embodiment, the color filter units 36 are directly formed on the blocking layer 35 on the light emitting units 33, and glass filters are omitted. Thus, the organic light emitting diode display in the present embodiment can be applied into large-sized displays and can meet the lighting and thinning requirements. Both of the blocking layer 35 and the package layer 37 are thin film package layers which have a smaller thickness than a glass substrate, and thus the organic light emitting diode display in the present disclosure can meet the lighting and thinning requirements and be applied into flexible displays.

### Second Embodiment

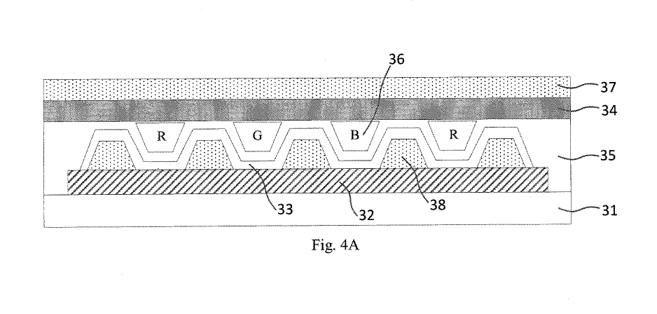

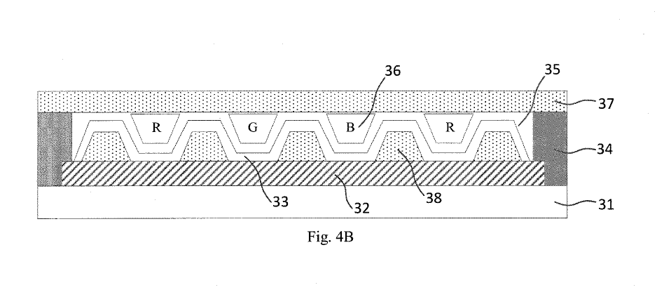

FIGS. 4A and 4B are schematic diagrams showing an organic light emitting diode display according to another embodiment of the present disclosure. The differences between the embodiment in FIGS. 4A and 4B and the embodiment in FIG. 3 reside in that the organic light emitting diode display further includes an adhesive layer 34, and the package layer 37 can server as a second substrate. The second substrate may be a flexible substrate or a rigid substrate. The flexible substrate includes a metal substrate, an organic polymer substrate, or metal oxide substrate and the like. As an example, the second substrate is an organic polymer substrate, for example, polyethylene terephthalate, polyether sulfone, polyethylene naphthalate, cycloolefin copolymer or polyimide. The rigid substrate includes a glass substrate, a quartz substrate and the like.

The adhesive layer 34 in the present embodiment may be disposed on the color filter units 36, or may be disposed at an edge of the first substrate 31. As shown in FIG. 4A, when the adhesive layer 34 is disposed on the color filter units 36, the adhesive layer 34 covers the color filter units 36, and the package layer 37 is attached to the color filter units 36 by means of the adhesive force of the adhesive layer 34 so as to package the organic light emitting diode display. As shown in FIG. 4B, the adhesive layer 34 is disposed at an edge of the first substrate 31, the package layer 37 is adhered to the first substrate 31 by the adhesive layer 34 so as to enclose the thin film transistor array 32 and the light emitting units 33 into a closed space formed by the first substrate 31, the package layer 37 and the adhesive layer 34.

The package layer 37 in the present embodiment, which may be a flexible substrate or a right substrate, plays a role of protection and water or oxygen resistance property and thereby can further enhance the package effect of the display.

Embodiments of the present disclosure further provide a method for manufacturing an organic light emitting diode display. The difference between the method in the present embodiment and the method as mentioned in the above embodiments resides in the step S4. Taking the organic light emitting diode display in FIG. 4B as an example, the manufacturing method may include the following steps.

In step S1, a thin film transistor array 32 is provided on a first substrate 31.

In step S2, a light emitting module is provided on the thin film transistor array 32, wherein the light emitting module includes a plurality of light emitting units 33 and a pixel-defining layer 38. The light emitting module may further include a blocking layer 35.

In step S3, color filter units 36 are provided on the light emitting module.

In step S4, an adhesive layer 34 is provided at an edge of the first substrate 31, a package layer 37 is provided on the color filter units 36, so that the package 37 is adhered to the first substrate 31 by the adhesive layer 34 and the package layer 37 covers the color filter units 36.

The package layer 37 in the present embodiment can serve as a second substrate. After step S3 is performed, gluelike materials of the adhesive layer 34 are coated at edges of the first substrate 31 by coating or spinning, then the package layer 37 is placed over the whole substrate 31, and the gluelike materials are cured by light or heating. The resulted adhesive layer 34 may have a thickness of 5 μm˜50 μm.

The adhesive layer 34 in the organic light emitting diode display as shown in FIG. 4A may be formed on the color filter units 36 using the same method, then the second substrate is placed over the whole substrate and the adhesive layer 34 is cured to complete the package.

The gluelike materials of the adhesive layer 34 may be, for example, acrylics, epoxies or combination thereof, or other photopolymerization or low temperature thermal polymerization materials.

By the above main steps, the preparation of the organic light emitting diode display is completed.

### Third Embodiment

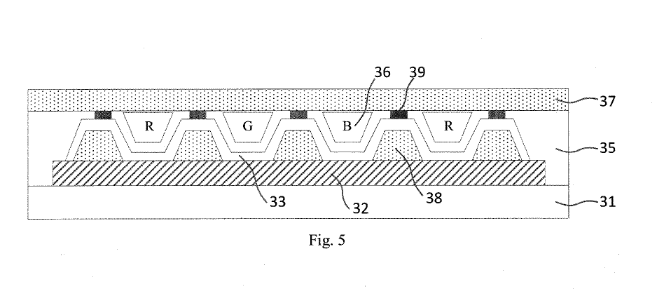

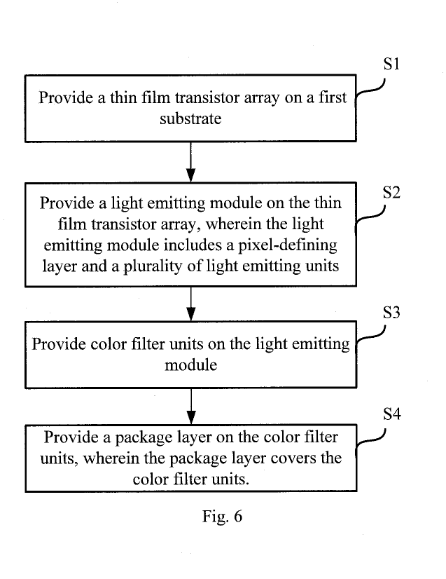

FIG. 5 is a schematic diagram showing an organic light emitting diode display according to another embodiment of the present disclosure. The difference of the embodiment and the embodiment in FIG. 3 resides in that a black matrix 39 is added among the photoresists of red, green and blue of the color filter units 36. The black matrix 39 is used to separate the photoresists of red, green and blue of the color filter units 36.

When the light emitting units 33 are turned on, the emitted light may propagate outwardly by passing through adjacent light emitting units. The black matrix 39 may block the light emitted from the light emitting units 33 from arriving at adjacent light emitting units. That is, by using the black matrix 39, problems such as inclined emission of light or light leakage can be addressed, and thereby color mixture can be prevented to enhance display contrast ratio.

An embodiment of the present disclosure further provides a method for manufacturing an organic light emitting diode display. The difference between the method in the present embodiment and the method as mentioned in the above embodiment resides in the step S3. The specific manufacturing method includes the following steps.

In step S1, a thin film transistor array 32 is provided on a first substrate 31.

In step S2, a light emitting module is provided on the thin film transistor array 32, wherein the light emitting module includes a plurality of light emitting units 33 and a pixel-defining layer 38. The light emitting module may further include a blocking layer 35.

In step S3, color filter units 36 and a black matrix 39 are provided on the light emitting module. The black matrix 39 is disposed between two adjacent color filter units 36.

The color filter units 36 and the black matrix 39 are manufactured by ink jet printing. The color filter units 36 may be formed firstly and then the black matrix 39. Alternatively, the black matrix 39 may be formed firstly, and then the color filter units 36.

Specifically, in an embodiment, by means of an ink jet device, patterns of the color filter units 36 or the black matrix 39 are formed on the blocking layer 35 by using a patterning process. The patterning process includes forming a color filter film or a black matrix film on the blocking layer 35 o the light emitting module, and performing exposure, developing and etching on the color filter film or the black matrix film to form the patterns of the color filter units 36 or the black matrix 39.

The black matrix 39 may formed by materials of good light shielding property, for example, resin materials doped with light shielding substances.

In step S4, a package layer 37 is provided on the color filter units 36. The package 37 covers the color filter units 36.

By the above main steps, the preparation of the organic light emitting diode display is completed.

While the present disclosure is described with reference to some exemplary embodiments, these exemplary embodiments are not for limiting the present disclosure. One of ordinary skill in this art can make various changes, amendments, substitutions, and modifications without departing from the spirit and scope of the present disclosure. Thus, the protection scope of the present disclosure shall be defined by appended claims.

What is claimed is:

1. An organic light emitting diode display, comprising:
a substrate;
a thin film transistor array disposed on the substrate;
a light emitting module comprising:
a pixel-defining layer disposed on the thin film transistor array and provided with a plurality of openings for defining positions of pixels; and
a plurality of light emitting units disposed on the thin film transistor array and in the openings of the pixel-defining layer;
color filter units disposed on the light emitting module and corresponding to positions of the plurality of light emitting units in the openings of the pixel-defining layer; and
a package layer disposed on the substrate to cover the color filter units.

2. The organic light emitting diode display according to claim 1, wherein the light emitting module further comprises a blocking layer disposed on the plurality of light emitting units and covering the plurality of light emitting units and the thin film transistor array.

3. The organic light emitting diode display according to claim 2, wherein the blocking layer is a thin film package layer.

4. The organic light emitting diode display according to claim 1, wherein the package layer is a thin film package layer.

5. The organic light emitting diode display according to claim 3, wherein the thin film package layer is made of a material selected from any one of oxide, nitride, oxynitride and fluoride.

6. The organic light emitting diode display according to claim 4, wherein the thin film package layer is made of a material selected from oxide, nitride, oxynitride or fluoride.

7. The organic light emitting diode display according to claim 1, further comprising:
an adhesive layer disposed on the color filter units;
wherein the package layer is attached to the color filter units via the adhesive layer.

8. The organic light emitting diode display according to claim 1, further comprising:
an adhesive layer disposed at an edge of the substrate;
wherein the package layer and the substrate are adhered with each other via the adhesive layer.

9. The organic light emitting diode display according to claim 7, wherein the package layer is a flexible layer or a rigid layer.

10. The organic light emitting diode display according to claim 8, wherein the package layer is a flexible layer or a rigid layer.

11. The organic light emitting diode display according to claim 1, further comprising:
a black matrix disposed between two adjacent color filter units.

12. The organic light emitting diode display according to claim 1, wherein the light emitting units are white light emitting units.

13. The organic light emitting diode display according to claim 1, wherein the light emitting units comprise individual red, green and blue light emitting units.

14. The organic light emitting diode display according to claim 1, wherein the substrate is a flexible substrate or a rigid substrate.

15. A method for manufacturing an organic light emitting diode display, comprising steps of:
S1: providing a thin film transistor array on a substrate;
S2: proving a light emitting module on the thin film transistor array having a pixel-defining layer and a plurality of light emitting units thereon;
S3: providing color filter units on the light emitting module; and
S4: providing a package layer on the color filter units, wherein the package layer covers the color filter units.

16. The method for manufacturing an organic light emitting diode display according to claim 15, wherein the light emitting module provided in the step S2 further comprises a blocking layer which is disposed on the plurality of light emitting units and covers the light emitting units and the thin film transistor array.

17. The method for manufacturing an organic light emitting diode display according to claim 15, wherein the step S4 further comprises: providing an adhesive layer on the color filter units such that the package layer is attached to the color filter units via the adhesive layer.

18. The method for manufacturing an organic light emitting diode display according to claim 15, wherein the step S4 further comprises: providing an adhesive layer at an edge of the substrate so that the package layer and the substrate are adhered with each other via the adhesive layer.

19. The method for manufacturing an organic light emitting diode display according to claim 15, wherein the step S3 further comprises: providing a black matrix on the light emitting module, wherein the black matrix is disposed between two adjacent color filter units.

20. The method for manufacturing an organic light emitting diode display according to claim 19, wherein the color filter units and the black matrix are manufactured by ink jet printing.
